(19) United States
(12) Patent Application Publication
(10) Pub. No.: US 2014/0266750 A1
(43) Pub. Date: Sep. 18, 2014

(54) APPARATUS AND METHOD FOR TESTING WORKING VOLTAGE OF CPU

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: MING YU, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/063,112

(22) Filed: Oct. 25, 2013

(30) Foreign Application Priority Data
Mar. 12, 2013 (CN) 2013100781590

(51) Int. Cl. G01R 31/30

(52) U.S. Cl. CPC G01R 31/3004
USPC 340/644; 702/64

(57) ABSTRACT

An apparatus for testing working voltage of a central processing unit (CPU) includes a programmable logic device (PLD) having a dummy load, a voltage regulating controller, a CPU socket and a south bridge. The CPU socket is electrically connected to the voltage regulating controller via a series voltage identification (SVID) bus. The south bridge outputs a CPU voltage determining signal. The dummy load is electrically connected to the voltage regulating controller via the SVID bus. The PLD receives the CPU voltage determining signal, and outputs a voltage requesting signal via the SVID bus. The voltage regulating controller receives the voltage requesting signal, and outputs a CPU working voltage to the CPU socket accordingly. The PLD detects the CPU working voltage on the CPU socket, and determines whether the CPU working voltage meets requirements of specification.

### BACKGROUND

1. Technical Field

The present disclosure relates to an apparatus and method for testing working voltage of a central processing unit (CPU).

2. Description of Related Art

With the rapid development of personal computers, high performance components in computers have increased electrical power demand of the personal computers. A CPU plays a crucial role in the stability of the computers. A working voltage of the CPU needs to be tested after the computer is manufactured. Conventional testing methods require the CPU installed in a CPU socket before the CPU can be tested. Most often, the computer fails the test because of a damaged CPU.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of an apparatus for testing working voltage of a CPU.

FIG. 2 is a flowchart of an embodiment of a method for testing working voltage of a CPU.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

FIG. 1 shows an apparatus for testing working voltage of a CPU in accordance with one embodiment. The apparatus includes a programmable logic device (PLD) 10, a switch unit 20, a central processing unit (CPU) socket 30, a voltage regulating controller 40, a south bridge 50 and an alarm unit 60.

The PLD 10 and the CPU socket 30 are electrically connected to the voltage regulating controller 40 via a series voltage identification (SVID) bus 80. When the south bridge 50 is power on, the south bridge 50 outputs a CPU voltage determining signal. The PLD 10 has a dummy load (not shown). The dummy load is electrically connected to the voltage regulating controller 40 via the SVID bus 80 when the switch unit 20 turns on. The PLD 10 receives the CPU voltage determining signal, and outputs a voltage requesting signal via the SVID bus 80. The voltage regulating controller 40 receives the voltage requesting signal, and outputs a CPU working voltage to the CPU socket 30 accordingly.

The PLD 10 detects the CPU working voltage on the CPU socket 30, and determines whether the CPU working voltage meets specification requirements. When the voltage regulating controller 40 receives the voltage requesting signal from the CPU socket 30 and the PLD 10 at the same time, the PLD 10 outputs an alarm signal to the alarm unit 60. The alarm unit 60 emits light or makes a sound when receiving the alarm signal. In one embodiment, the alarm unit 60 is a light emitting diode (LED) or a buzzer.

FIG. 2 shows a flowchart of a method for testing working voltage of a CPU in accordance with one embodiment. Depending on the embodiment, certain steps described below may be removed, while others may be added, and the sequence of the steps may be altered. In one embodiment, the method for testing working voltage of a CPU utilizing the above-described system includes the following steps:

S201: the PLD 10 starts up and initializes;

S202: the PLD 10 determines whether the CPU is installed in the CPU socket 30; if the CPU is not installed in the CPU socket 30, the procedure goes to step S203; if the CPU is installed in the CPU socket 30, the procedure goes to step S209;

S203: the PLD 10 determines whether the switch unit 20 turns on;

S204: if the switch unit 20 turns on, the dummy load is electrically connected to the voltage regulating controller 40 via the SVID bus 80; if the switch unit 20 turns off, the procedure goes to step S208;

S205: the PLD 10 determines whether the south bridge 50 is power on; if the south bridge 50 is power off, returns to step S204; if the south bridge 50 is power on, the procedure goes to step S206;

S206: the south bridge 50 outputs the CPU voltage determining signal to the PLD 10; the PLD 10 outputs the voltage requesting signal to the voltage regulating controller 40 via the SVID bus 80; the voltage regulating controller 40 outputs the working voltage to the CPU socket 30 according to the voltage requesting signal;

S207: the PLD 10 detects the CPU working voltage on the CPU socket 30, and determines whether the CPU working voltage meets requirements of specification;

S208: the PLD 10 outputs the alarm signal to the alarm unit 60; the alarm unit 60 activates to alarm;

S209: the PLD 10 determines whether the switch unit 20 turns on; if the switch unit 20 turns off, the procedure enters step S205; if the switch unit 20 turns on, the procedure enters step S208.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. An apparatus for testing working voltage of a central processing unit (CPU), comprising:
a programmable logic device (PLD) comprising a dummy load;
a voltage regulating controller;
a CPU socket electrically connected to the voltage regulating controller via a series voltage identification (SVID) bus; and
a south bridge adapted to output a CPU voltage determining signal; wherein the dummy load is electrically connected to the voltage regulating controller via the SVID bus; the PLD receives the CPU voltage determining signal, and outputs a voltage requesting signal via the SVID bus; the voltage regulating controller receives the voltage requesting signal and outputs a CPU working voltage to the CPU socket accordingly; the PLD detects the CPU working voltage on the CPU socket, and determines whether the CPU working voltage meets requirements of specification.

2. The apparatus for testing working voltage of claim 1, wherein the south bridge outputs the CPU voltage determining signal when the south bridge is powered on.

3. The apparatus for testing working voltage of claim 2, further comprising a switch unit electrically connected to the PLD; and the dummy load is electrically connected to the voltage regulating controller via the SVID bus when the switch unit is turned on.

4. The apparatus for testing working voltage of claim 1, further comprising an alarm unit electrically connected to the PLD; when the voltage regulating controller receives the voltage requesting signal from the CPU socket and the PLD at the same time, the PLD outputs an alarm signal to the alarm unit, and the alarm unit activates to alarm when receives the alarm signal.

5. The apparatus for testing working voltage of claim 4, wherein the alarm unit is a light emitting diode (LED) or a buzzer; and the alarm unit activates to emit light or make a sound when receives the alarm signal.

6. A method for testing working voltage of a central processing unit (CPU), the method comprises the following steps:
determining whether the CPU is installed in a CPU socket by a programmable logic device (PLD);
if the CPU is not installed in the CPU socket, the PLD determines whether a switch unit is turned on;
if the switch unit is turned off, the PLD outputs an alarm signal to an alarm unit; the alarm unit activates to alarm;
if the switch unit is turned on, a dummy load in the PLD is electrically connected to a voltage regulating controller via a series voltage identification (SVID) bus;
determining whether the south bridge is powered on by the PLD; if the south bridge is powered on, the south bridge outputs a CPU voltage determining signal to the PLD; the PLD outputs a voltage requesting signal to the voltage regulating controller via the SVID bus; the voltage regulating controller outputs a working voltage to the CPU socket according to the voltage requesting signal; and
detecting the CPU working voltage on the CPU socket and determining whether the CPU working voltage meets requirements of specification by the PLD;
if the CPU is installed in the CPU socket, the PLD determines whether the switch unit is turned on;
if the switch unit is turned off, returns to the step of determining whether the south bridge is powered on by the PLD;
if the switch unit is turned on, the PLD outputs an alarm signal to the alarm unit; the alarm unit activates to alarm.

7. The method for testing working voltage of claim 6, wherein when the voltage regulating controller receives the voltage requesting signal from the CPU socket and the PLD at the same time, the PLD outputs the alarm signal.

8. The method for testing working voltage of claim 7, wherein the PLD comprises a dummy load; and the dummy load is electrically connected to the voltage regulating controller via the SVID bus when the switch unit is turned on.
